(19) United States
(12) Patent Application Publication
(10) Pub. No.: US 2024/0290398 A1
(43) Pub. Date: Aug. 29, 2024

(54) MEMORY DEVICE AND STORAGE DEVICE INCLUDING MEMORY DEVICE

(71) Applicant: SK hynix Inc., Gyeonggi-do (KR)

(72) Inventor: Byoung Sung YOU, Gyeonggi-do (KR)

(21) Appl. No.: 18/346,784

(22) Filed: Jul. 4, 2023

(30) Foreign Application Priority Data
Feb. 23, 2023 (KR) 10-2023-0024363

(51) Int. Cl. G11C 16/34; G11C 16/04; G11C 16/28

(52) U.S. Cl. CPC G11C 16/3404; G11C 16/0433; G11C 16/28

(57) ABSTRACT

A memory device may include a plurality of memory blocks and a peripheral circuit configured to check a shift in threshold voltages of target select transistors by simultaneously applying a reference voltage to target select lines that are coupled to the plurality of memory blocks.

### CROSS-REFERENCES TO RELATED APPLICATION

The present application claims priority under 35 U.S.C. § 119(e) to Korean application number 10-2023-0024363, filed on Feb. 23, 2023, which is incorporated herein by reference in its entirety.

### BACKGROUND

### 1. Technical Field

Embodiments of the present disclosure relate to a storage device including a memory device.

### 2. Related Art

A storage device may store data provided by an external device, in response to a write request from the external device. Furthermore, the storage device may provide the external device with data that has been stored in the storage device, in response to a read request from the external device. The external device is an electronic device capable of processing data, and may include a computer, a digital camera, or a mobile phone. The storage device may operate by being embedded in the external device, or may operate by being manufactured in a separable form and coupled to the external device. The storage device may include a memory device for storing data and a controller for controlling the memory device.

Data that has been stored in the memory device may be damaged by various causes. For this reason, a check operation for checking damage to data needs to be periodically performed on the memory device, but the execution of frequent check operations may deteriorate operation performance of the storage device. Accordingly, there is a need for a check operation which can be performed rapidly and efficiently.

### SUMMARY

In an embodiment of the present disclosure, a memory device may include: a plurality of memory blocks; and a peripheral circuit configured to check a shift in threshold voltages of target select transistors by simultaneously applying a reference voltage to target select lines that are coupled to the plurality of memory blocks.

In an embodiment of the present disclosure, a memory device may include: a plurality of memory blocks; and a peripheral circuit configured to: read read-values from respective bit lines that are coupled to the plurality of memory blocks in common, and check a shift in threshold voltages of target select transistors that are included in the plurality of memory blocks based on the read-values, wherein the target select transistors coupled to a corresponding bit line of the bit lines are configured to determine, by their operations, each of the read values.

In an embodiment of the present disclosure, a storage device may include: a memory device configured to perform a check operation for checking a shift in threshold voltages of target select transistors by simultaneously applying a reference voltage to target select lines that are coupled to a plurality of memory blocks; and a controller configured to control the check operation.

In an embodiment of the present disclosure, a memory device may include: cell arrays of respective groups of rows and a common group of columns; and a peripheral circuit configured to determine, based on first and second signals, threshold-voltage-shifts of target cells, each of which belongs to a corresponding target row respectively selected from the row groups, wherein: the first signal represents a number of failed columns in the column group, a number of failed target cells among the target cells belonging to each of the failed columns is greater than a threshold, each of the failed target cells is turned on or off by a reference voltage simultaneously applied to the target rows, and the second signal represents a tolerable number of the failed columns.

### BRIEF DESCRIPTION OF THE DRAWINGS

FIG. 1 is a block diagram illustrating a storage device according to an embodiment of the present disclosure.

FIG. 2 is a block diagram illustrating a configuration of a memory die that is included in the memory device of FIG. 1 according to an embodiment of the present disclosure.

FIG. 3 is a circuit diagram illustrating a first memory block according to an embodiment of the present disclosure.

FIG. 4 is a diagram illustrating a threshold voltage distribution of drain select transistors and a threshold voltage distribution of source select transistors according to an embodiment of the present disclosure.

FIG. 5 is a circuit diagram illustrating a configuration of a connection circuit according to an embodiment of the present disclosure.

FIG. 6 is a circuit diagram illustrating a configuration of a first check circuit according to an embodiment of the present disclosure.

FIG. 7 is a diagram illustrating a process of updating DSL left check results of first to fourth planes according to an embodiment of the present disclosure.

FIG. 8 is a diagram illustrating a setting command and a check command according to an embodiment of the present disclosure.

FIG. 9 is a flowchart illustrating a check operation according to an embodiment of the present disclosure.

### DETAILED DESCRIPTION

Hereinafter, embodiments of the present disclosure will be described in detail with reference to the accompanying drawings.

The embodiments provide a memory device capable of checking damage to data rapidly and efficiently, and a storage device including a memory device.

Namely, the memory device and the storage device including a memory device according to embodiments can check damage to data rapidly and efficiently.

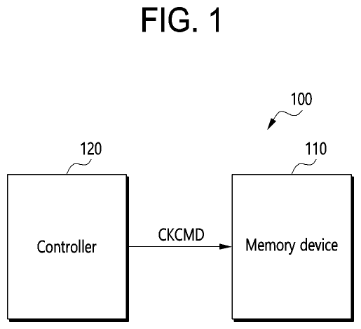

FIG. 1 is a block diagram illustrating a storage device 100 according to an embodiment of the present disclosure.

The storage device 100 may store data that has been received from an external device, for example, a host device in response to a write request from the host device. Furthermore, the storage device 100 may provide the host device with data that has been stored in the storage device 100, in response to a read request from the host device.

The storage device 100 may include a personal computer memory card international association (PCMCIA) card, a smart media card, a memory stick, various multimedia cards (e.g., an MMC, an eMMC, an RS-MMC, and MMC-micro), secure digital (SD) cards (e.g., SD, mini-SD, and micro-SD), universal flash storage (UFS), or a solid state drive (SSD).

The storage device 100 may include a memory device 110 and a controller 120.

The memory device 110 may operate under the control of the controller 120. Operations of the memory device 110 may include a read operation, a write operation (i.e., a program operation), and an erase operation.

The memory device 110 may include various types of memory, such as NAND flash memory, 3-D NAND flash memory, NOR flash memory, resistive random access memory (RRAM), phase change random access memory (PRAM), magnetoresistive random access memory (MRAM), ferroelectric random access memory (FRAM), or spin transfer torque random access memory (STTRAM).

The controller 120 may control an overall operation of the storage device 100. The controller 120 may control the memory device 110 in response to a request from the host device. For example, the controller 120 may store data that is transmitted by the host device in the memory device 110, in response to a write request from the host device. For example, the controller 120 may read data from the memory device 110 and transmit the read data to the host device, in response to a read request from the host device.

Furthermore, the controller 120 may control the memory device 110 to perform a management operation that is internally necessary for the controller 120, independently of the host device, that is, although a request is not received from the host device. For example, the management operation may include a wear leveling operation, a garbage collection operation, and an erase operation. According to an embodiment, the management operation may be performed in response to a request from the host device.

The controller 120 may control the memory device 110 to perform a check operation by transmitting a check command CKCMD to the memory device 110. As will be described in detail below, a check operation according to an embodiment can significantly improve operation performance of the storage device 100 because the check operation can effectively predict the deterioration of data that has been stored in the memory device 110, for a short time.

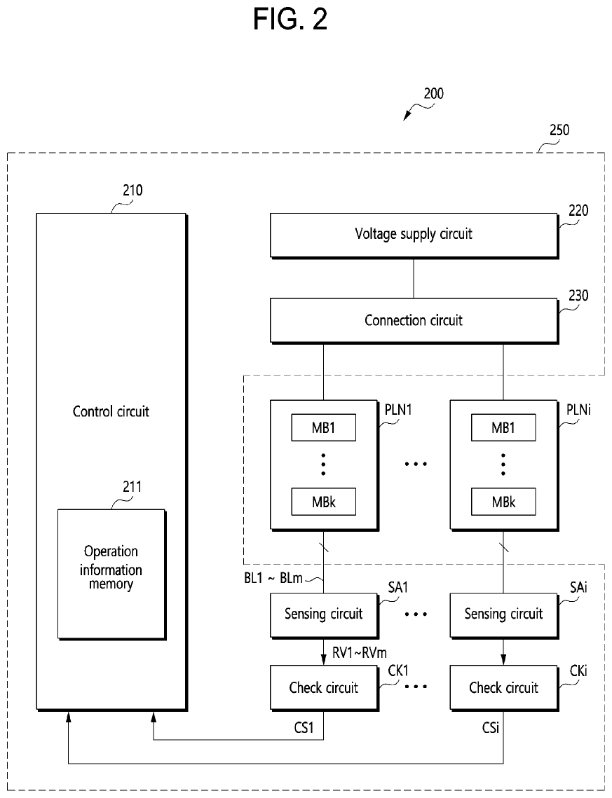

FIG. 2 is a block diagram illustrating a configuration of a memory die 200 that is included in the memory device 110 of FIG. 1 according to an embodiment of the present disclosure.

Referring to FIG. 2, the memory device 110 may include one or more memory dies including the memory die 200. The memory dies may independently perform operations (e.g., a program operation, a read operation, and an erase operation) under the control of the controller 120. One or more memory dies may be constructed similarly to the memory die 200, and may operate similarly to the memory die 200.

The memory die 200 may include a peripheral circuit 250 and one or more planes PLN1 to PLNi.

The peripheral circuit 250 may check a shift in the threshold voltages of target select transistors by simultaneously applying a reference voltage to target select lines that are coupled to a plurality of memory blocks MB1 to MBk of the one or more planes PLN1 to PLNi. The target select lines may be drain select lines or source select lines, on which the check operation is to be performed. The check operation may be an operation of checking the shift in the threshold voltages of the target select transistors coupled to the target select lines.

The peripheral circuit 250 may include a control circuit 210, a voltage supply circuit 220, a connection circuit 230, one or more sensing circuits SA1 to SAi, and one or more check circuits CK1 to CKi.

The control circuit 210 may control an overall operation of the memory die 200 under the control of the controller 120. The control circuit 210 may control components that are included in the memory die 200 by transmitting control signals (not illustrated) to the components.

The control circuit 210 may include an operation information memory 211. The operation information memory 211 may store various types of information in relation to an operation of the memory device 110. The information that is stored in the operation information memory 211 may include various parameters that have been set by the controller 120. The control circuit 210 may store information in the operation information memory 211 and change the stored information, under the control of the controller 120. As will be described later, the control circuit 210 may receive a setting command relating to a check operation from the controller 120, and may store, in the operation information memory 211, parameters that have been included in the setting command.

The control circuit 210 may control an operation of the memory die 200 with reference to the operation information memory 211. The control circuit 210 may generate control signals for controlling components that are included in the memory die 200 with reference to the operation information memory 211.

In the check operation, the control circuit 210 may store, in the operation information memory 211, the check results of the planes PLN1 to PLNi in response to check signals CS1 to CSi respectively from the check circuits CK1 to CKi. The control circuit 210 may store a state value of the check operation in the operation information memory 211 based on the check results of the planes PLN1 to PLNi.

The voltage supply circuit 220 may generate various operation voltages to be applied to the planes PLN1 to PLNi, under the control of the control circuit 210.

The connection circuit 230 may couple the voltage supply circuit 220 and the planes PLN1 to PLNi so that operation voltages generated by the voltage supply circuit 220 are applied to the planes PLN1 to PLNi, under the control of the control circuit 210.

The planes PLN1 to PLNi may be coupled to the sensing circuits SA1 to SAi, respectively. The sensing circuits SA1 to SAi may be coupled to the check circuits CK1 to CKi, respectively. The planes PLN1 to PLNi may have similar configurations and operations. The sensing circuits SA1 to SAi may have similar configurations and operations. The check circuits CK1 to CKi may have similar configurations and operations.

The first plane PLN1, the first sensing circuit SA1, and the first check circuit CK1 are described as examples. The first plane PLN1 may be a group of first to k-th memory blocks MB1 to MBk that are coupled to the first sensing circuit SA1 through first to m-th bit lines BL1 to BLm. The first plane PLN1 may include one or more first to k-th memory blocks MB1 to MBk. Each of the memory blocks MB1 to MBk may be a unit by which the memory device 110 performs an erase operation. That is, data that has been stored in each of the memory blocks may be simultaneously erased.

The first sensing circuit SA1 may output first to m-th read values RV1 to RVm respectively corresponding to the first to m-th bit lines BL1 to BLm by sensing a state (i.e., a current or a voltage) of each of the first to m-th bit lines BL1 to BLm. The first sensing circuit SA1 may be configured as various structures capable of sensing the state of each of the first to m-th bit lines BL1 to BLm.

In a check operation, the first check circuit CK1 may generate a first check signal CS1, based on the first to m-th read values RV1 to RVm that are output by the first sensing circuit SA1. The first check signal CS1 having a logic high value may mean a “fail”, for example. The first check signal CS1 having a logic low value may mean a “pass”, for example.

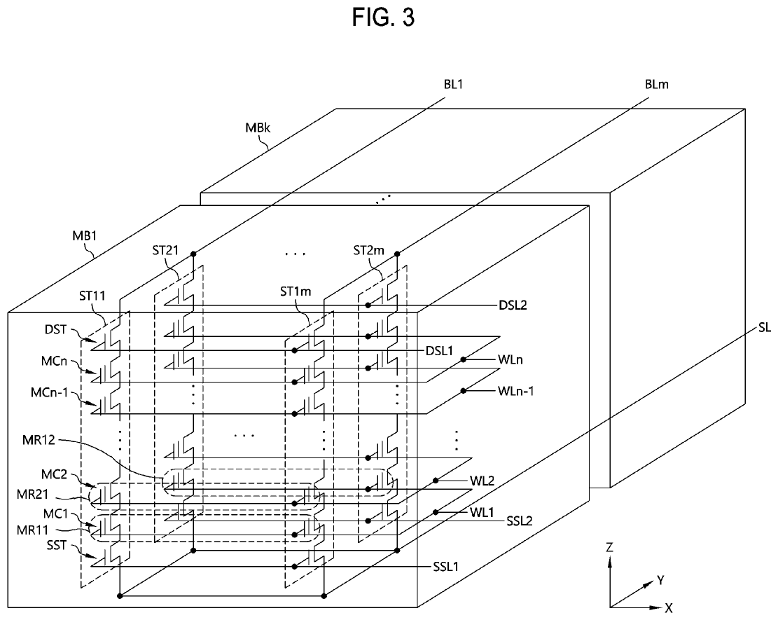

FIG. 3 is a circuit diagram illustrating a first memory block MB1 according to an embodiment of the resent disclosure. Each of the first to k-th memory blocks MB1 to MBk in FIG. 2 may be configured similarly to the first memory block MB1 in FIG. 3.

Referring to FIG. 3, the first memory block MB1 may include strings ST11 to ST1m and ST21 to ST2m. Each of the strings ST11 to ST1m and ST21 to ST2m may extend in a vertical direction (or a Z direction). Furthermore, m strings may be arranged in a row direction (or an X direction) within the first memory block MB1. FIG. 2 illustrates that two strings have been arranged in a column direction (or a Y direction), but this is for convenience of description. Three or more strings may be arranged in the column direction (or the Y direction).

The strings ST11 to ST1m and ST21 to ST2m may be identically configured. For example, the string ST11 may include a source select transistor SST, memory cells MC1 to MCn, and a drain select transistor DST that are coupled in series between a source line SL and a first bit line BL1. A source of the source select transistor SST may be coupled to the source line SL. A drain of the drain select transistor DST may be coupled to the first bit line BL1. The memory cells MC1 to MCn may be coupled in series between the source select transistor SST and the drain select transistor DST.

Gates of the source select transistors SST of strings that are

arranged in the same row may be coupled to the same source select line. For example, gates of source select transistors of the strings ST11 to ST1m that are arranged in a first row may be coupled to a first source select line SSL1. For example, gates of source select transistors of the strings ST21 to ST2m that are arranged in a second row may be coupled to a second source select line SSL2.

Unlike the example illustrated in FIG. 2, according to an embodiment, gates of the source select transistors of strings that are arranged in a predetermined number of rows may be coupled to one source select line in common. For example, when a predetermined number is 2, the gates of the source select transistors of the strings ST11 to ST1m and ST21 to ST2m that are arranged in the first and second rows may be coupled to the first source select line SSL1 in common. Furthermore, gates of the source select transistors of strings (not illustrated) that are arranged in third and fourth rows may be coupled to the second source select line SSL2 in common.

In another embodiment, gates of the source select transistors of all of the strings of the first memory block MB1 may be coupled to one source select line in common.

Gates of drain select transistors of strings that are arranged in the same row may be coupled to the same drain select line. For example, gates of drain select transistors of the strings ST11 to ST1m that are arranged in the first row may be coupled to a first drain select line DSL1. For example, gates of drain select transistors of the strings ST21 to ST2m that are arranged in the second row may be coupled to a second drain select line DSL2.

Strings that are arranged in the same column may be coupled to the same bit line. For example, the strings ST11 and ST21 that are arranged in a first column may be coupled to the first bit line BL1. For example, strings ST1m and ST2m that are arranged in an m-th column may be coupled to an m-th bit line BLm.

Gates of memory cells that are disposed at the same location in the vertical direction may be coupled to the same word line. For example, memory cells that are disposed at the same location in a direction perpendicular to the memory cell MC1 in the strings ST11 to ST1m and ST21 to ST2m may be coupled to a first word line WL1.

Memory cells that are coupled to the same word line in the same row, among memory cells, may constitute one memory region. For example, memory cells that are coupled to the first word line WL1 in the first row may constitute one memory region MR11. For example, memory cells that are coupled to the first word line WL1 in the second row may constitute one memory region MR12. For example, memory cells that are coupled to a second word line WL2 in the first row may constitute one memory region MR21. Each word line may be coupled to a plurality of memory regions depending on the number of rows.

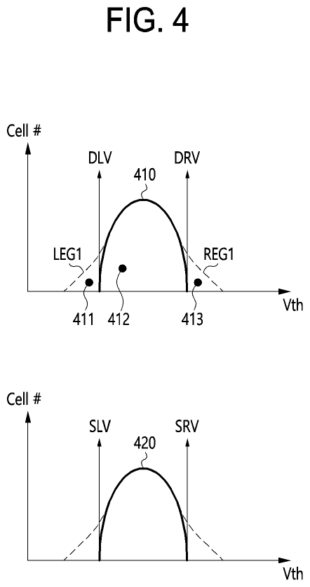

FIG. 4 is a diagram illustrating a threshold voltage distribution 410 of drain select transistors and a threshold voltage distribution 420 of source select transistors according to an embodiment of the present disclosure.

Referring to FIG. 4, the drain select transistors may be controlled to form the threshold voltage distribution 410. For example, a program operation may be performed on the drain select transistors in a way similar to a program operation for memory cells. Specifically, when a program voltage is applied to a drain select line, charges may be injected into the floating gate of each drain select transistor, and the drain select transistor may have a threshold voltage having a predetermined range that corresponds to the threshold voltage distribution 410. Accordingly, when a voltage (e.g., a pass voltage) greater than the threshold voltage distribution 410 is applied to the drain select line, the drain select transistor may couple a corresponding string to a bit line. Furthermore, when a voltage (e.g., a non-selection voltage) smaller than the threshold voltage distribution 410 is applied to the corresponding drain select line, the drain select transistor might not couple the corresponding string to the bit line.

Memory cells may also form a plurality of threshold voltage distributions through a program operation. However, forms of the threshold voltage distributions of the memory cells may be changed due to various causes (e.g., an abnormal temperature or the lapse of time). This may mean the deterioration of data that has been stored in the memory cells. It may be difficult to frequently check a change in the threshold voltage distributions of a large number of memory cells because too much time is taken. On the other hand, if such a check is not performed at a proper time, the deterioration of the reliability of the storage device 100 may be caused.

Drain select transistors may have substantially the same structures as memory cells. If the states of threshold voltage distributions of memory cells have been changed, the state of the threshold voltage distribution 410 of the drain select transistors may also have been similarly changed. For example, a left edge LEG of the threshold voltage distribution 410 may be left shifted, and a right edge REG of the threshold voltage distribution 410 may be right shifted. Accordingly, in order to estimate a change in the threshold voltage distributions of memory cells, the storage device 100 may check a change in the threshold voltage distribution 410 of the drain select transistors through a check operation. Since a check operation for a smaller number of drain select transistors than memory cells can be rapidly performed, overhead of the storage device 100 for maintaining the reliability of the storage device 100 can be greatly reduced.

For example, a left shift at the left edge LEG may be determined based on a drain select line (DSL) left reference voltage DLV. When the DSL left reference voltage DLV is applied to a target drain select line (i.e., a DSL on which a check operation is performed), a drain select transistor 411 having a threshold voltage lower than the DSL left reference voltage DLV, among drain select transistors that are coupled to the target drain select line, may be turned on. Such a drain select transistor 411 that has been turned on may be a drain select transistor, the threshold voltage of which has been left shifted. Furthermore, when the DSL left reference voltage DLV is applied to the target drain select line, a drain select transistor 412 having a threshold voltage higher than the DSL left reference voltage DLV, among the drain select transistors that are coupled to the target drain select line, may be turned off. As the left shift at the left edge LEG becomes severe, the number of turned-on drain select transistors may increase among the drain select transistors coupled to the target drain select line.

Similarly, a right shift at the right edge REG may be determined based on a DSL right reference voltage DRV. The DSL right reference voltage DRV may be higher than the DSL left reference voltage DLV. When the DSL right reference voltage DRV is applied to the target drain select line, a drain select transistor 413 having a threshold voltage higher than the DSL right reference voltage DRV, among the drain select transistors that are coupled to the target drain select line, may be turned off. Such a drain select transistor 413 that has been turned off may be a drain select transistor the threshold voltage of which has been right shifted. Furthermore, when the DSL right reference voltage DRV is applied to the target drain select line, the drain select transistor 412 having a threshold voltage lower than the DSL right reference voltage DRV, among the drain select transistors that are coupled to the target drain select line, may be turned on. As the right shift at the right edge REG becomes severe, the number of turned-off drain select transistors may increase among the drain select transistors coupled to the target drain select line.

Source select transistors may be constructed and may operate similarly to the drain select transistors. The threshold voltage distribution 420 of the source select transistors may be similar to the threshold voltage distribution 410 of the drain select transistors. Accordingly, the aforementioned check operation may also be performed on the source select transistors. A left shift and right shift in the source select transistors may be determined based on a source select line (SSL) left reference voltage SLV and an SSL right reference voltage SRV. The SSL right reference voltage SRV may be higher than the SSL left reference voltage SLV. The SSL left reference voltage SLV may be the same as or different from the DSL left reference voltage DLV. The SSL right reference voltage SRV may be the same as or different from the DSL right reference voltage DRV. The DSL left reference voltage DLV, the DSL right reference voltage DRV, the SSL left reference voltage SLV, and the SSL right reference voltage SRV may be set by the controller 120. A reference voltage that is mentioned below may mean any one of the DSL left reference voltage DLV, the DSL right reference voltage DRV, the SSL left reference voltage SLV, and the SSL right reference voltage SRV depending on whether a left shift or a right shift is checked on a drain select line or a source select line.

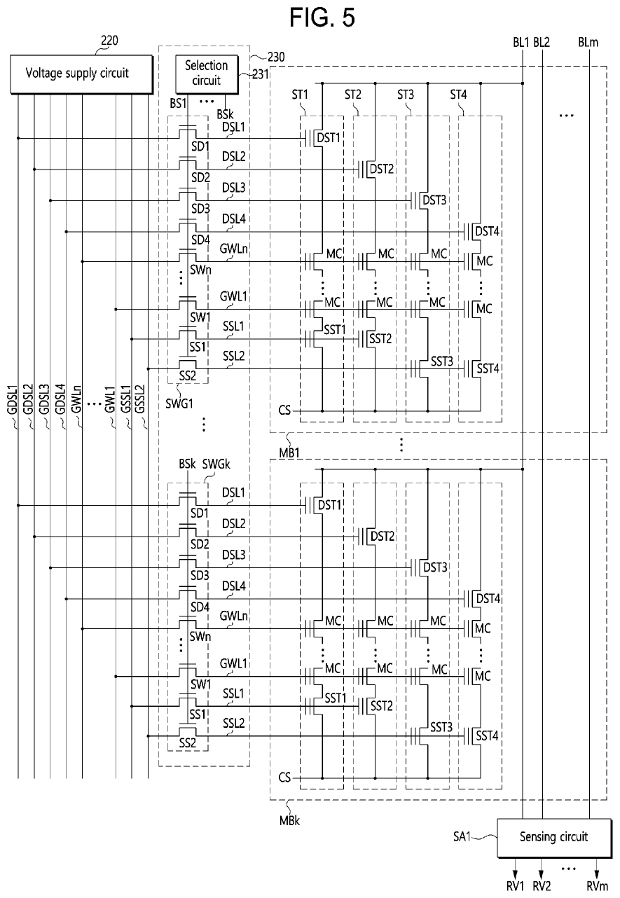

FIG. 5 is a circuit diagram illustrating a configuration of a connection circuit according to an embodiment of the present disclosure. A method of simultaneously performing a check operation on target select lines of the first to k-th memory blocks MB1 to MBk that are included in the first plane PLN1 will be described with reference to FIG. 5. The memory device 110 can maximize performance of the check operation by simultaneously checking the target select lines of the first to k-th memory blocks MB1 to MBk.

Referring to FIG. 5, the voltage supply circuit 220 may apply a predetermined operation voltage to each of global drain select lines GDSL1 to GDSL4, global word lines GWL1 to GWLn, and global source select lines GSSL1 and GSSL2. The operation voltage may include a DSL left reference voltage DLV, a DSL right reference voltage DRV, an SSL left reference voltage SLV, an SSL right reference voltage SRV, a pass voltage, and a non-selection voltage.

The connection circuit 230 may selectively couple the voltage supply circuit 220 and the first to k-th memory blocks MB1 to MBk. The connection circuit 230 may include switch groups SWG1 to SWGk and a select circuit 231.

Each of the switch groups SWG1 to SWGk may couple the voltage supply circuit 220 and each of the first to k-th memory blocks MB1 to MBk in response to each of select signals BS1 to BSk. The switch groups SWG1 to SWGk may be similarly constructed and may similarly operate. The switch group SWG1 may be described as an example. When being enabled in response to the select signal BS1, switches SD1 to SD4 that are included in the switch group SWG1 may couple the global drain select lines GDSL1 to GDSL4 and first to fourth drain select lines DSL1 to DSL4 of the first memory block MB1, respectively. When being enabled in response to the select signal BS1, switches SW1 to SWn that are included in the switch group SWG1 may couple the global word lines GWL1 to GWLn and first to n-th word lines WL1 to WLn of the first memory block MB1, respectively. When being enabled in response to the select signal BS1, switches SS1 and SS2 that are included in the switch group SWG1 may couple the global source select lines GSSL1 and GSSL2 and source select lines SSL1 and SSL2 of the first memory block MB1, respectively.

The select circuit 231 may selectively enable the switch groups SWG1 to SWGk through the select signals BS1 to BSk. The select circuit 231 may enable the switch group SWG1 by enabling the select signal BS1, and may enable the switch group SWGk by enabling the select signal BSk. Under the control of the control circuit 210, the select circuit 231 may enable, in a check operation, all the select signals BS1 to BSk so that the voltage supply circuit 220 is coupled to all first to k-th memory blocks MB1 to MBk.

The first to k-th memory blocks MB1 to MBk may be similarly constructed. The first memory block MB1 may be described as an example. The first memory block MB1 may be coupled to the first to fourth drain select lines DSL1 to DSL4, the first to n-th word lines WL1 to WLn, and the source select lines SSL1 and SSL2. The number of first to fourth drain select lines DSL1 to DSL4 and the number of source select lines SSL1 and SSL2 may be examples. Furthermore, the first memory block MB1 may include strings ST1 to ST4 that are coupled to the first bit line BL1. Although not illustrated, the first memory block MB1 may also include strings that are coupled to the second to m-th bit lines BL2 to BLm, similarly to the strings ST1 to ST4.

The first sensing circuit SA1 may sense a state (i.e., a current or a voltage) of each of the first to m-th bit lines BL1 to BLm when a check operation is performed on target select lines of the first to k-th memory blocks MB1 to MBk, and may output first to m-th read values RV1 to RVm respectively corresponding to the states of the first to m-th bit lines BL1 to BLm. When the number of target select transistors (i.e., select transistors that are coupled to the target select lines in the respective first to k-th memory blocks MB1 to MBk) that have been turned on with respect to each bit line is greater than a predetermined reference number, the first sensing circuit SA1 may output a read value as a first value (e.g., 1) with respect to the corresponding bit line. Furthermore, when the number of target select transistors that have been turned on with respect to each bit line is a predetermined reference number or less, the first sensing circuit SA1 may output a read value as a second value (e.g., 0) with respect to the corresponding bit line. A left reference number may be used as the predetermined reference number in a left check operation for checking a left shift. A right reference number may be used as the predetermined reference number in a right check operation for checking a right shift.

The first drain select lines DSL1 of the first to k-th memory blocks MB1 to MBk may be selected as target select lines. In this state, in order to simultaneously check a left shift in first drain select transistors DST1 that are coupled to the first drain select lines DSL1 of the first to k-th memory blocks MB1 to MBk, a left check operation may be performed on the first drain select lines DSL1 of the first to k-th memory blocks MB1 to MBk.

Specifically, first, all switch groups SWG1 to SWGk may be enabled in response to the first to k-th select signals BS1 to BSk that have been enabled.

The voltage supply circuit 220 may apply a DSL left reference voltage DLV to the first global drain select line GDSL1. The DSL left reference voltage DLV may be simultaneously applied to the first drain select lines DSL1 of the first to k-th memory blocks MB1 to MBk via the first global drain select line GDSL1.

Furthermore, the voltage supply circuit 220 may apply a pass voltage to the global word lines GWL1 to GWLn and the first global source select line GSSL1. The pass voltage may be simultaneously applied to the first to n-th word lines WL1 to WLn and the first source select line SSL1 via the global word lines GWL1 to GWLn and the first global source select line GSSL1. That is, the pass voltage may be simultaneously applied to the first to n-th word lines WL1 to WLn and the first source select line SSL1 that are coupled to the same strings ST1 as the first drain select lines DSL1. The pass voltage may be a high voltage which causes turning on a memory cell or a select transistor.

Furthermore, the voltage supply circuit 220 may simultaneously apply a non-selection voltage to global select lines (i.e., the second to fourth global drain select lines GDSL2 to GDSL4 and the second global source select line GSSL2) to which the pass voltage has not been applied. The non-selection voltage may be a low voltage (e.g., a ground voltage) which causes turning off a select transistor.

Each of the first drain select transistors DST1 that are coupled to the first bit line BL1 in the first to k-th memory blocks MB1 to MBk may be turned on or off in response to the DSL left reference voltage DLV that has been applied to the first drain select lines DSL1 of the first to k-th memory blocks MB1 to MBk. Memory cells MC and a first source select transistor SST1 that are coupled to the first bit line BL1 in the first to k-th memory blocks MB1 to MBk may be turned on in response to the pass voltage that has been applied to the first to n-th word lines WL1 to WLn and the first source select line SSL1.

As a result, a current or a voltage may be derived in the first bit line BL1, depending on the number of first drain select transistors DST1 that have been turned on (i.e., the threshold voltages of the first drain select transistors DST1 have been left shifted) in response to the DSL left reference voltage DLV, among the first drain select transistors DST1 that are coupled to the first bit line BL1, and the number of first drain select transistors DST1 that have been turned off (i.e., the threshold voltages of the first drain select transistors DST1 have not been left shifted) in response to the DSL left reference voltage DLV, among the first drain select transistors DST1 that are coupled to the first bit line BL1. The first sensing circuit SA1 may output the read value RV1 of the first bit line BL1 by sensing the current or voltage of the first bit line BL1. For example, when the number of first drain select transistors DST1 that have been turned on is greater than a predetermined left reference number, the first sensing circuit SA1 may output a value of one (1) as the read value RV1 of the first bit line BL1. For example, when the number of first drain select transistors DST1 that have been turned on is a predetermined left reference number or less, the first sensing circuit SA1 may output a value of zero (0) as the read value RV1 of the first bit line BL1.

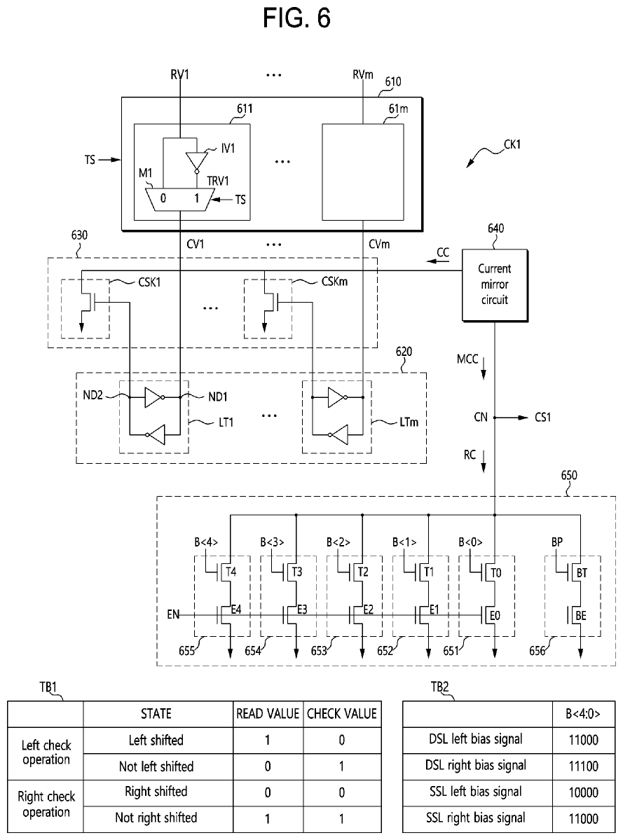

When the DSL left reference voltage DLV is applied to the first drain select lines DSL1, first drain select transistors (not illustrated) that are coupled to the first drain select lines DSL1 and the second to m-th bit lines BL2 to BLm may also similarly operate. The first sensing circuit SA1 may output a value of one (1) or zero (0) as each of the read values RV2 to RVm of the second to m-th bit lines BL2 to BLm. As a result, when the first to m-th read values RV1 to RVm of the first to m-th bit lines includes many values of one (1), it may be determined that the threshold voltages of the first drain select transistors DST1 of the first plane PLN1 have been severely left shifted. Whether the first to m-th read values RV1 to RVm include many values of one (1) may be determined by the first check circuit CK1 as will be described with reference to FIG. 6.

Furthermore, in order to simultaneously check a right shift in the first drain select transistors DST1 that are coupled to the first drain select lines DSL1 of the first to k-th memory blocks MB1 to MBk, a right check operation may be performed on the first drain select lines DSL1. The right check operation may be similar to the aforementioned left check operation except that a DSL right reference voltage DRV is used instead of the DSL left reference voltage DLV and a right reference number is used instead of the left reference number. For example, when the number of first drain select transistors DST1 that have been turned on (i.e., the threshold voltages of the first drain select transistors DST1 have not been right shifted) is greater than a predetermined right reference number, the first sensing circuit SA1 may output a value of one (1) as the read value RV1 of the first bit line BL1. For example, when the number of first drain select transistors DST1 that have been turned on is a predetermined right reference number or less, the first sensing circuit SA1 may output a value of zero (0) as the read value RV1 of the first bit line BL1. As a result, when the first to m-th read values RV1 to RVm of the first to m-th bit lines BL1 to BLm include many values of zero (0), it may be determined that the threshold voltages of the first drain select transistors DST1 of the first plane PLN1 have been severely right shifted. Whether the first to m-th read values RV1 to RVm include many values of zero (0) may be determined by the first check circuit CK1 as will be described with reference to FIG. 6.

A left check operation and a right check operation in which each of the second to fourth drain select lines DSL2 to DSL4 and each of the first and second source select lines SSL1 and SSL2 are target select lines may be performed similarly to the aforementioned left check operation and right check operation for the first drain select line DSL1.

FIG. 6 is a circuit diagram illustrating a configuration of the first check circuit CK1 according to an embodiment of the present disclosure.

The first check circuit CK1 may include an inversion circuit 610, a data storage circuit 620, a check current generation circuit 630, a current mirror circuit 640, and a reference current generation circuit 650.

When a right check operation is performed, the inversion circuit 610 may output, as check values CV1 to CVm, non-inverted values of the first to m-th read values RV1 to RVm that are transmitted by the first sensing circuit SA1. When a left check operation is performed, the inversion circuit 610 may invert the first to m-th read values RV1 to RVm that are transmitted by the first sensing circuit SA1, and may output the inverted values of the first to m-th read values RV1 to RVm as the check values CV1 to CVm. This is for enabling the first check circuit CK1 to check a shift by using the same check value (e.g., a value of zero (0)) regardless of a “left-shifted” state or a “right-shifted” state although the “left-shifted” state and the “right-shifted” state generate different read values (i.e., values of one (1) and zero (0)) in the left check operation and the right check operation, as will be described with reference to Table TB1. The inversion circuit 610 may selectively invert the first to m-th read values RV1 to RVm in response to an inversion signal TS. The inversion signal TS may indicate whether a left check operation is being performed or a right check operation is being performed. The inversion signal TS may be generated by the control circuit 210.

According to an embodiment, the inversion circuit 610 may include a plurality of sub-inversion circuits 611 to 61m. The sub-inversion circuits 611 to 61m may receive the read values RV1 to RVm, respectively, and may output the check values CV1 to CVm, respectively, in response to the inversion signal TS. The sub-inversion circuits 611 to 61m may be similarly constructed and may similarly operate. For example, the sub-inversion circuit 611 may receive the read value RV1, and may output the check value CV1 in response to the inversion signal TS. The sub-inversion circuit 611 may include an inverter IV1 and a MUX M1. The inverter IV1 may receive the read value RV1, and may output an inverted value TRV1 of the read value RV1. The MUX M1 may output the read value RV1 or the inverted value TRV1 as the check value CV1 in response to the inversion signal TS. For example, the MUX may output the read value RV1 as the check value CV1 when the inversion signal TS is disabled, and may output the inverted value TRV1 as the check value CV1 when the inversion signal TS is enabled.

As a result, as illustrated in Table TB1, a read value and check value of each bit line may be determined based on a state of target select transistors that are coupled to target select lines of the first to k-th memory blocks MB1 to MBk in a left check operation and a right check operation. The “left-shifted” state may be a state in which the number of select transistors having threshold voltages left shifted in each bit line is greater than a left reference number. A “not-left-shifted” state may be a state in which the number of select transistors having threshold voltages left shifted in each bit line is a left reference number or less. The “right-shifted” state may be a state in which the number of select transistors having threshold voltages not right shifted in each bit line is a right reference number or less. A “not-right-shifted” state may be a state in which the number of select transistors having threshold voltages not right shifted in each bit line is greater than a right reference number.

Unlike the example illustrated in Table TB1, according to an embodiment, the inversion circuit 610 may output, as the check values CV1 to CVm, non-inverted values of the first to m-th read values RV1 to RVm in a left check operation, and inverted values of the first to m-th read values RV1 to in a right check operation.

The data storage circuit 620 may store the check values CV1 to CVm that are transmitted by the inversion circuit 610. The data storage circuit 620 may include latches LT1 to LTm for storing the check values CV1 to CVm, respectively. The latches LT1 to LTm may be similarly constructed and may similarly operate. The latch LT1 may be described as an example. The latch LT1 may store a check value in a first node ND1, and may store an inverted value of the check value in a second node ND2. The latch LT1 may include inverters that are coupled in parallel in a reverse direction, but may be constructed as another structure capable of storing a check value according to an embodiment.

The check current generation circuit 630 may generate a check current CC in response to the check values CV1 to CVm that have been stored in the data storage circuit 620. The check current generation circuit 630 may include check current sink circuits CSK1 to CSKm that are coupled to the second nodes ND2 of the latches LT1 to LTm, respectively. The check current sink circuits CSK1 to CSKm may each sink the check current CC in response to inverted values of the check values CV1 to CVm that have been stored in the second nodes ND2 of the latches LT1 to LTm, respectively. When a value of one (1) is stored in the second node ND2 of each of the latches LT1 to LTm, each of the check current sink circuits CSK1 to CSKm may sink the check current CC. As a result, as a left shift in target select transistors becomes severe, more check current CC may be sunk in a left check operation. Furthermore, as a right shift in target select transistors becomes severe, more check current CC may be sunk in a right check operation.

The current mirror circuit 640 may generate a mirrored check current MCC that flows into a check node CN by mirroring the check current CC. The current mirror circuit 640 may generate the mirrored check current MCC having the same size as the check current CC. The current mirror circuit 640 may be constructed as various structures capable of mirroring the check current CC.

The reference current generation circuit 650 may sink a reference current RC from the check node CN, in response to a bias signal B<4:0>, a bypass signal BP, and an enable signal EN. The bias signal B<4:0> may consist of a plurality of bits. The reference current generation circuit 650 may include reference current sink circuits 651 to 655 and a bypass circuit 656 that are coupled in parallel between the check node CN and a ground node. The number of illustrated reference current sink circuits 651 to 655 may be an example.

The reference current sink circuits 651 to 655 may be similarly constructed and may similarly operate. The reference current sink circuit 651 may be described as an example. The reference current sink circuit 651 may include a bias transistor T0 and an enable transistor E0 that are coupled in series between the check node CN and the ground node. The bias transistor T0 may be enabled in response to a first bit B<0> of the bias signal B<4:0>, and thus may couple the check node CN and the enable transistor E0. The enable transistor E0 may be enabled in response to the enable signal EN, and thus may couple the bias transistor T0 and the ground node.

Bias transistors T0 to T4 that are included in the reference current sink circuits 651 to 655, respectively, may be enabled in response to bits of the bias signal B<4:0>, respectively. The bias transistors T0 to T4 may have different sizes. For example, the bias transistor T0 may make a current having the same size as a current that is sunk when one check current sink circuit of the check current generation circuit 630 enabled flow through the bias transistor T0. Furthermore, the bias transistors T1 to T4 may have the sizes of currents that are 2 times, 4 times, 8 times, and 16 times the size of a current of the bias transistor T0, respectively. Accordingly, the bias transistors T1 to T4 may make currents that are 2 times, 4 times, 8 times, and 16 times the size of a current of the bias transistor T0 flow through the bias transistors T1 to T4, respectively.

The bypass circuit 656 may include a bypass transistor BT and a bypass enable transistor BE that are coupled in series between the check node CN and the ground node. The bypass transistor BT may be enabled in response to the bypass signal BP, and thus may couple the check node CN and the bypass enable transistor BE. The bypass enable transistor BE may be enabled in response to the enable signal EN, and thus may couple the bypass transistor BT and the ground node.

According to an embodiment, the bypass circuit 656 may be omitted, and the reference current generation circuit 650 may sink the reference current RC from the check node CN based on the bias signal B<4:0> and the enable signal EN.

As illustrated in Table TB2, the bias signal B<4:0> may be divided into a DSL left bias signal, a DSL right bias signal, an SSL left bias signal, and an SSL right bias signal. The DSL left bias signal may be used in a left check operation in which a target select line is a drain select line. The DSL right bias signal may be used in a right check operation in which a target select line is a drain select line. The SSL left bias signal may be used in a left check operation in which a target select line is a source select line. The SSL right bias signal may be used in a right check operation in which a target select line is a source select line. The illustrated bias signal B<4:0> is an example, and may be set by the controller 120. The bias signal B<4:0> may correspond to a maximum tolerable number of values of zero (0), among the check values CV1 to CVm that are stored in the data storage circuit 620. For example, the DSL left bias signal may correspond to a maximum tolerable number of target drain select transistors having threshold voltages left shifted in each plane. The bias signal B<4:0> may be set so that each of the reference current sink circuits 651 to 655 sinks more reference current RC as the maximum tolerable number is increased.

The check node CN may output a first check signal CS1. When the mirrored check current MCC is greater than the reference current RC in the check node CN, the first check signal CS1 may be output as a logic high value. The first check signal CS1 having the logic high value may mean a “fail”, that is, that the threshold voltages of target select transistors of the first plane PLN1 have been severely shifted. In contrast, when the mirrored check current MCC is the reference current RC or less in the check node CN, the first check signal CS1 may be output as a logic low value. The first check signal CS1 having the logic low value may mean a “pass”, that is, that the threshold voltages of target select transistors of the first plane PLN1 have not been severely shifted.

The check operation for the first plane PLN1, which has been described with reference to FIGS. 5 and 6, may be simultaneously performed on other planes. Accordingly, the present embodiment can rapidly check the reliability of the entire memory die 200.

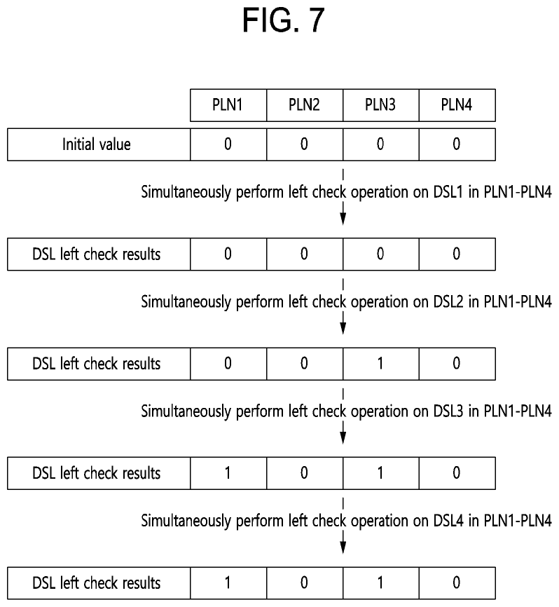

FIG. 7 is a diagram illustrating a process of updating DSL left check results of the first to fourth planes PLN1 to PLN4 according to an embodiment of the present disclosure. The number of planes PLN1 to PLN4, that is, 4, may be an example.

Referring to FIG. 7, DSL left check results may be generated as the results of left check operations for the first to fourth drain select lines DSL1 to DSL4, which have been sequentially performed with respect to each plane. The control circuit 210 may store the DSL left check results of the first to fourth planes PLN1 to PLN4 in the operation information memory 211. The DSL left check results of the first to fourth planes PLN1 to PLN4 may have a 4-bit bitmap. The control circuit 210 may maintain corresponding DSL left check results as a previous value when the check signal of each plane indicates a pass, and may update corresponding DSL left check results with a fail value (e.g., a value of one (1)) when the check signal of each plane indicates a fail. After all left check operations are sequentially performed on the first to fourth drain select lines DSL1 to DSL4, the controller 120 may determine the final DSL left check results. The controller 120 may determine that a left shift in the threshold voltages is not severe in the first to fourth drain select lines DSL1 to DSL4 of a corresponding plane when the final DSL left check results indicate a pass value (e.g., a value of zero (0)). The controller 120 may determine that a left shift in threshold voltages is severe in at least one of the first to fourth drain select lines DSL1 to DSL4 of a corresponding plane when the final DSL left check results indicate a fail value (e.g., a value of one (1)).

Specifically, the DSL left check results of the first to fourth planes PLN1 to PLN4 may have a pass value, that is, initial values of zero (0).

As the results of left check operations for the first drain select line DSL1, which have been simultaneously performed in the first to fourth planes PLN1 to PLN4, when all of the first to fourth check signals CS1 to CS4 of the first to fourth planes PLN1 to PLN4 indicate a pass, DSL left check results may be maintained to a value of zero (0).

As the results of left check operations for the second drain select line DSL2, which have been simultaneously performed in the first to fourth planes PLN1 to PLN4, when only the third check signal CS3 of the third plane PLN3 indicates a fail, only the DSL left check results of the third plane PLN3 may be updated with a value of one (1), and the remaining DSL left check results may be maintained as previous values.

As the results of left check operations for the third drain select line DSL3, which have been simultaneously performed in the first to fourth planes PLN1 to PLN4, when only the first check signal CS1 of the first plane PLN1 indicates a fail, only the DSL left check results of the first plane PLN1 may be updated with a value of one (1), and the remaining DSL left check results may be maintained as previous values.

As the results of left check operations for the fourth drain select line DSL4, which have been simultaneously performed in the first to fourth planes PLN1 to PLN4, when all of the first to fourth check signals CS1 to CS4 of the first to fourth planes PLN1 to PLN4 indicate a pass, all of the DSL left check results may be maintained as previous values.

Accordingly, the controller 120 may determine that a left shift in threshold voltages is severe in at least one drain select line of each of the first plane PLN1 and the third plane PLN3 with reference to the final DSL left check results.

According to an embodiment, the memory device 110 may sequentially perform left check operations on only some of the first to fourth drain select lines DSL1 to DSL4 by setting a check mode under the control of the controller 120. In this case, the memory device 110 may generate DSL left check results based on the results of the left check operations for the some drain select lines.

Similarly, as the results of right check operations for the first to fourth drain select lines DSL1 to DSL4, which have been sequentially performed, DSL right check results of the first to fourth planes PLN1 to PLN4 may be generated. As the results of left check operations for the first and second source select lines SSL1 and SSL2, which have been sequentially performed, SSL left check results of the first to fourth planes PLN1 to PLN4 may be generated. As the results of right check operations for the first and second source select lines SSL1 and SSL2, which have been sequentially performed, SSL right check results of the first to fourth planes PLN1 to PLN4 may be generated.

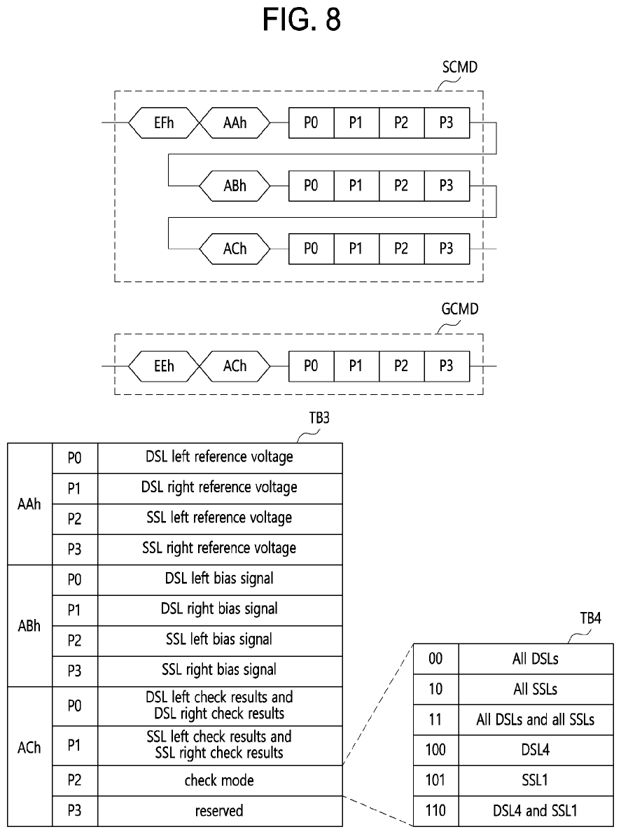

FIG. 8 is a diagram illustrating the setting command SCMD and the check command GCMD according to an embodiment of the present disclosure.

Referring to FIG. 8, the controller 120 may transmit the setting command SCMD for a check operation to the memory device 110. The controller 120 may set operation information of the check operation through the setting command SCMD. The memory device 110 may store, in the operation information memory 211, parameters that are included in the setting command SCMD in response to the setting command SCMD.

Specifically, the setting command SCMD may include a command EFh, first to third addresses AAh, ABh, and ACh, and first to fourth parameters P0 to P3 corresponding to each of the first to third addresses AAh, ABh, and ACh. The command EFh may be a set feature command, for example, but an embodiment is not limited to the example. Each of the first to third addresses AAh, ABh, and ACh may indicate locations at which the first to fourth parameters P0 to P3 are stored in the operation information memory 211. The number of parameters P0 to P3, that is, 4, may be an example.

Furthermore, the controller 120 may transmit the check command GCMD to the memory device 110. The controller 120 may identify all check results (i.e., DSL left check results, DSL right check results, SSL left check results, and SSL right check results of the planes PLN1 to PLNi) of check operations through the check command GCMD. The memory device 110 may transmit, to the controller 120, the check results from the operation information memory 211 in response to the check command GCMD.

Specifically, the check command GCMD may include a command EEh, a third address ACh, and parameters P0 to P3 corresponding to the third address ACh. The command EEh may be a get feature command, for example, but an embodiment is not limited to the example.

Table TB3 describes the first to fourth parameters P0 to P3 corresponding to each of the first to third addresses AAh, ABh, and ACh.

The first to fourth parameters P0 to P3 corresponding to the first address AAh may indicate a DSL left reference voltage DLV, a DSL right reference voltage DRV, an SSL left reference voltage SLV, and an SSL right reference voltage SRV, respectively.

The first to fourth parameters P0 to P3 corresponding to the second address ABh may indicate a DSL left bias signal B<4:0>, a DSL right bias signal B<4:0>, an SSL left bias signal B<4:0>, and an SSL right bias signal B<4:0>, respectively.

The first to third parameters P0 to P2 corresponding to the third address ACh may indicate DSL left check results and DSL right check results of the planes PLN1 to PLNi, SSL left check results and SSL right check results of the planes PLN1 to PLNi, and the check mode, respectively. The third parameter P3 corresponding to the third address ACh may be reserved.

According to an embodiment, the memory device 110 may neglect the first and second parameters P0 and P1 corresponding to the third address ACh in the setting command SCMD.

Table TB4 describes values of the check mode. The check mode may indicate select lines on which a check operation will be performed. For example, when a value of the check mode is binary 00, a check operation may be performed on only all drain select lines. According to an embodiment, a check operation may be performed on only a specific select line that has been determined to be weak in the memory die 200. For example, when a value of the check mode is binary 100, a check operation may be performed on only the fourth drain select line DSL4.

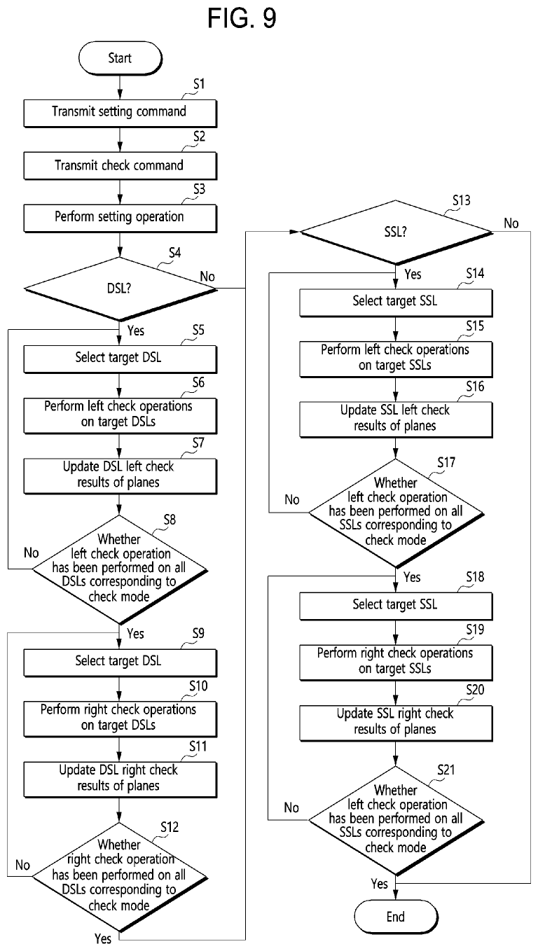

FIG. 9 is a flowchart illustrating a check operation according to an embodiment of the present disclosure.

In operation S1, the controller 120 may transmit, to the memory device 110, the setting command SCMD for a check operation.

In operation S2, the controller 120 may transmit the check command CKCMD to the memory device 110. The check command CKCMD may indicate that the memory device 110 needs to perform the check operation. According to an embodiment, when the memory device 110 includes a plurality of memory dies, the controller 120 may select a target memory die on which a check operation will be performed, among the plurality of memory dies. The controller 120 may transmit, to the memory device 110, the check command CKCMD including the address of the target memory die.

In operation S3, the memory device 110 may perform a setting operation of the check operation in response to the check command CKCMD. The setting operation of the check operation may include an operation of selecting all of the memory blocks MB1 to MBk of all of the planes PLN1 to PLNi of the target memory die, an operation of initializing the sensing circuits SA1 to SAi and the check circuits CK1 to CKi, and an operation of generating various operation voltages. Operation performance of a check operation can be maximized because a setting operation of the check operation is performed only once at the beginning although the check operation is repeatedly performed on a plurality of select lines corresponding to the check mode.

In operation S4, the memory device 110 may determine whether to perform a check operation on a drain select line based on the check mode. When it is determined that the check operation will be performed on the drain select line, the procedure may proceed to operation S5. When it is determined that the check operation will not be performed on the drain select line, the procedure may proceed to operation S13.

In operation S5, the memory device 110 may select a target drain select line on which a left check operation has not been performed yet, among one or more drain select lines corresponding to the check mode.

In operation S6, the memory device 110 may perform the left check operations on the target drain select lines of the planes PLN1 to PLNi.

In operation S7, the memory device 110 may update DSL left check results of the planes PLN1 to PLNi in the operation information memory 211. According to an embodiment, the DSL left check results of each of the planes PLN1 to PLNi may have an initial value of a pass value (e.g., a value of zero (0)). The memory device 110 may maintain corresponding DSL left check results as a previous value when the check signal of each plane indicates a pass, and may update corresponding DSL left check results with a fail value when the check signal of each plane indicates a fail.

In operation S8, the memory device 110 may determine whether the left check operation has been performed on all of the drain select lines corresponding to the check mode. If the left check operations have been performed on all of the drain select lines corresponding to the check mode, the procedure may proceed to operation S9. If the left check operations have not been performed on all of the drain select lines corresponding to the check mode, the procedure may proceed back to operation S5.

In operation S9, the memory device 110 may select a target drain select line on which a right check operation has not been performed yet, among one or more drain select lines corresponding to the check mode.

In operation S10, the memory device 110 may perform right check operations on the target drain select lines of the planes PLN1 to PLNi.

In operation S11, the memory device 110 may update DSL right check results of the planes PLN1 to PLNi in the operation information memory 211. According to an embodiment, the DSL right check results of each of the planes PLN1 to PLNi may have an initial value of a pass value (e.g., a value of zero (0)). The memory device 110 may maintain corresponding DSL right check results as a previous value when the check signal of each plane indicates a pass, and may update corresponding DSL right check results as a fail value when the check signal of each plane indicates a fail.

In operation S12, the memory device 110 may determine whether the right check operation has been performed on all of the drain select lines corresponding to the check mode. If the right check operations have been performed on all of the drain select lines corresponding to the check mode, the procedure may proceed to operation S13. If the right check operations have not been performed on all of the drain select lines corresponding to the check mode, the procedure may proceed back to operation S9.

In operation S13, the memory device 110 may determine whether a check operation will be performed on a source select line based on the check mode. When it is determined that the check operation will be performed on the source select line, the procedure may proceed to operation S14. When it is determined that the check operation will not be performed on the source select line, the procedure may be terminated.

Operations S14 to S21 may be performed similarly to operations S5 to S12 except that operations S14 to S21 are performed on the source select line instead of the drain select line.

According to the procedure illustrated in FIG. 9, the right check operation is performed subsequently to the left check operation, but the left check operation may be performed subsequently to the right check operation according to an embodiment.

According to an embodiment, after operation S21, the memory device 110 may store a state value in the operation information memory 211. The memory device 110 may store the state value as a fail value when at least one of all of the check results (i.e., the DSL left check results, the DSL right check results, the SSL left check results, and the SSL right check results) of the planes PLN1 to PLNi is a fail value. The controller 120 may transmit a state read command to the memory device 110 in order to check the state value. The memory device 110 may transmit, to the controller 120, the state value from a state register in response to the state read command. When the state value transmitted by the memory device 110 is a fail value, the controller 120 may transmit the check command GCMD to the memory device 110 in order to check all check results of the planes PLN1 to PLNi.

The above description is merely a description of the technical spirit of the embodiments, and those skilled in the art may change and modify the embodiments in various ways without departing from the essential characteristic of the embodiments. Accordingly, the disclosed embodiments should not be construed as limiting the technical spirit of the embodiments, but should be construed as describing the technical spirit of the embodiments. The technical spirit of the embodiments is not restricted by the embodiments. The range of protection of the embodiment should be construed based on the following claims, and all technical spirits within an equivalent range of the embodiments should be construed as being included in the scope of rights of the embodiments. Furthermore, the embodiments may be combined to form additional embodiments.

What is claimed is:

1. A memory device comprising:
a plurality of memory blocks; and
a peripheral circuit configured to check a shift in threshold voltages of target select transistors by simultaneously applying a reference voltage to target select lines that are coupled to the plurality of memory blocks.

2. The memory device according to claim 1, wherein the peripheral circuit checks the shift further by:
applying a pass voltage to word lines and select lines that are coupled to strings, to which the target select lines are coupled, and
applying a non-selection voltage to select lines, to which the pass voltage has not been applied.

3. The memory device according to claim 2, wherein:
the pass voltage is a high voltage causing turn-on of a memory cell or a select transistor, and
the non-selection voltage is a low voltage causing turn-off of a select transistor.

4. The memory device according to claim 1,
wherein the peripheral circuit checks the shift further by:
sensing states of bit lines that are coupled to the memory blocks when applying the reference voltage, and
determining read values respectively corresponding to the states of the bit lines, and
wherein the peripheral circuit checks the shift based on the read values.

5. The memory device according to claim 4, wherein the peripheral circuit senses each of the states based on a number of target select transistors which are turned on in response to the reference voltage among target select transistors coupled to a corresponding bit line and a number of target select transistors which are turned off in response to the reference voltage among the target select transistors coupled to the corresponding bit line.

6. The memory device according to claim 4,
wherein the reference voltage is a left reference voltage when the shift is a left shift, and
wherein the reference voltage is a right reference voltage when the shift is a right shift.

7. The memory device according to claim 6, wherein the peripheral circuit checks the shift further by:
generating a check current based on the read values, and
comparing the check current and a reference current, and
generating, based on a result of the comparing, a check signal indicating that the shift is severe.

8. The memory device according to claim 7, wherein the peripheral circuit generates the check current by:
determining, as check values, inverted values of the read values when the read values are determined by applying the left reference voltage to the target select lines,
determining, as the check values, the read values when the read values are determined by applying the right reference voltage to the target select lines, and
generating the check current based on the check values.

9. The memory device according to claim 7, wherein the peripheral circuit compares the check current and the reference current by:
generating, when the shift is the left shift, the reference current based on a left bias signal corresponding to a maximum tolerable number of target select transistors having threshold voltages left shifted in the memory blocks, and
generating, when the shift is the right shift, the reference current based on a right bias signal corresponding to a maximum tolerable number of target select transistors having threshold voltages right shifted in the memory blocks.

10. A memory device comprising:
a plurality of memory blocks; and
a peripheral circuit configured to:
read read-values from respective bit lines that are coupled to the plurality of memory blocks in common, and
check a shift in threshold voltages of target select transistors that are included in the plurality of memory blocks based on the read-values,
wherein the target select transistors coupled to a corresponding bit line of the bit lines are configured to determine, by their operations, each of the read values.

11. The memory device according to claim 10,
wherein the peripheral circuit reads the read-values from the respective bit lines by applying a first reference voltage to the target select transistors, and
wherein the peripheral circuit checks the shift by checking whether the threshold voltages are lower than the first reference voltage based on inverted values of the read-values.

12. The memory device according to claim 10,
wherein the peripheral circuit reads the read-values from the respective bit lines by applying a second reference voltage to the target select transistors, and
wherein the peripheral circuit checks the shift by checking whether the threshold voltages are higher than the second reference voltage based on the read-values.

13. A storage device comprising:
a memory device configured to perform a check operation for checking a shift in threshold voltages of target select transistors by simultaneously applying a reference voltage to target select lines that are coupled to a plurality of memory blocks; and
a controller configured to control the check operation.

14. The storage device according to claim 13, wherein the controller controls the check operation by setting the reference voltage to a left reference voltage when the shift is a left shift and to a right reference voltage when the shift is a right shift.

15. The storage device according to claim 13, wherein the controller controls the check operation by setting a left bias signal when the shift is a left shift and a right bias signal when the shift is a right shift.

16. The storage device according to claim 13, wherein the memory device performs the check operation by:
sensing a state of bit lines that are coupled to the memory blocks when applying the reference voltage,
determining read-values respectively corresponding to the states of the bit lines, and
checking the shift based on the read-values.

17. The storage device according to claim 16,
wherein the reference voltage is a left reference voltage when the shift is a left shift, and
wherein the reference voltage is a right reference voltage when the shift is a right shift.

18. The storage device according to claim 17, wherein the memory device performs the check operation further by:
generating a check current based on the read values,
comparing the check current and a reference current, and
generating, based on a result of the comparing, a check signal indicating that the shift is severe.

19. The storage device according to claim 18, wherein the memory device generates the check current by:
determining, as check values, inverted values of the read-values when the read-values are determined by applying the left reference voltage to the target select lines,
determining, as the check values, the read-values when the read-values are determined by applying the right reference voltage to the target select lines, and
generating the check current based on the check values.

20. The storage device according to claim 18, wherein the memory device compares the check current and the reference current by:
generating, when the shift is the left shift, the reference current based on a left bias signal corresponding to a maximum tolerable number of target select transistors having threshold voltages left shifted in the memory blocks, and
generating, when the shift is the right shift, the reference current based on a right bias signal corresponding to a maximum tolerable number of target select transistors having threshold voltages right shifted in the memory blocks.
